(19) United States
(12) Patent Application Publication
(10) Pub. No.: US 2008/0169516 A1
(43) Pub. Date: Jul. 17, 2008

(54) Semiconductor devices for alleviating well proximity effects

(75) Inventor: Shine Chung, Taipei Hsien (TW)

Correspondence Address: Howard Chen, Esq.;Kirkpatrick & Lockhart Preston Gates Ellis LLP, Suite 1700, 55 Second Street, San Francisco, CA, 94105, US

(73) Assignee: Taiwan Semiconductor Manufacturing Co., Ltd.

(21) Appl. No.: 11/654,829

(22) Filed: Jan. 17, 2007

(51) Int. Cl. H01L 27/088

(52) U.S. Cl. 257/401; 257/E27.081

(57) ABSTRACT

A semiconductor device is disclosed for alleviating well proximity effects. The semiconductor device comprises a well in a substrate; and a transistor with an active region and a gate of 0.13 um or less in gate length, wherein the gate is entirely within or extended to outside of the well, and a minimum spacing between an edge of the active region and an edge of the well is at least 3 times the gate length.

### BACKGROUND

The present invention relates generally to integrated circuit (IC) design rule generation, and more particularly, to a method for defining distances between device channel regions to well edges to alleviate well proximity effects.

N-well proximity effect is a newly discovered phenomenon since 130 nm technologies. In case of a PMOS device inside an N-well silicon, after a Shallow Trench Isolation (STI) was fabricated, a photoresist is put on the silicon to block ion implantation so that N-well region is defined. Since the N-well implant requires high energy and large dose ions, so that the photoresist has to be very thick which inevitably has tall slanted sidewalls. During ion implantation, ions scattered laterally just inside the photo-resist edge will be able to emerge from the photo-resist. These may be implanted into the silicon within the area that will become a transistor active-region later in the process. The depth and concentration of the implant ions will depend on the angle and energy of the scattered ions. The details of the lateral scattering depend on the mass of the incoming ions and the mass of the species in the photo-resist from which they are scattered. Whether or not there is a significant effect on the threshold voltage depends on the overall width of the device, the location of the device relative to the mask edge, the lateral range of the effect, and the density and depth of the scattered ions relative to those intentionally implanted in that region.

FIG. 1 is a cross-sectional view of an N-well during its formation by ion implantation. An N-well 110 is formed by implanting N-well ion 120 in a P-substrate 130. Non-N-well regions are covered by a photo-resist 140 to block the N-well ion implant 120 from reaching the P-substrate 130. Formation of the N-well 110 comes after the formation of a shallow-trench-isolation (STI) 150. Referring to FIG. 1, a border region 145 is depicted to be proximal to an edge of the photoresist 140. Some of the N-well implant ions 120 hitting this border region 145 may scatter out of the photo-resistor 140 and enter into an edge area 160 of the N-well 110, so that the edge area 160 receives a greater amount of N-well ion implantation dosage. If a subsequent PMOS device is built inside the N-well edge area 160, its characteristics, such as threshold voltage (Vt) and source-drain saturation current (Idsat) will be different from a PMOS device built away from the N-well edge area 160. This is often called N-well proximity effect, which affects not only PMOS devices inside the N-well but also NMOS devices outside the N-well. Further, the space of a device to the well edge affects device performance either in channel length (L) or channel width (W) direction.

In order to prevent device variations due to N-well proximity effects, sufficient spacing between the device active region and the N-well edges is needed. FIG. 2 is a layout diagram showing a transistor inside an odd shaped N-well 210. The N-well 210 is odd shaped to present various distances between a transistor and an N-well 210 edge. The transistor is defined by a poly-silicon gate 220 and an active region 230. The N-well proximity effect can be described by the following equation, in which a parameter SC stands for the average distance between a gate area of a MOS transistor and a well edge.

$$\begin{matrix}{SC}_{eff} = \{ \frac{1}{{W}_{drawn} \cdot {L}_{drawn}} \cdot [ {\sum }_{i = 1}^{n} ( {W}_{i} \cdot {\int }_{{SC}_{i}}^{{SC}_{i} + {L}_{drawn}} \frac{1}{{x}^{2}} d x ) + \\ { {\sum }_{i = n + 1}^{m} ( {L}_{i} \cdot {\int }_{{SC}_{i}}^{{SC}_{i} + {W}_{drawn}} \frac{1}{{y}^{2}} d y ) ] \}}^{- 0.5} \\ = \{ \frac{1}{{W}_{drawn} \cdot {L}_{drawn}} \cdot [ {\sum }_{i = 1}^{n} ( {W}_{i} \cdot ( \frac{1}{{SC}_{i}} - \frac{1}{{SC}_{i} + {L}_{drawn}} ) ) + \\ { {\sum }_{i = n + 1}^{m} ( {L}_{i} \cdot ( \frac{1}{{SC}_{i}} - \frac{1}{{SC}_{i} + {W}_{drawn}} ) ) ] \}}^{- 0.5}\end{matrix} \qquad ( Eq . 1 )$$

Eq. 1 is based on averaging areas between active regions and well edges, and can model implant behaviors accurately.

While conventional methods, such as the one represented by Eq. 1, are available for calculating the distance necessary for the spacing between a device and the N-well edges, however, these solutions require long complicated equations calculating many parameters in order to get an accurate spacing distance between the device and the N-well edges. Such methods are very difficult to be put into practical use due to their complexities.

Therefore, it is desirable to device a simple yet effective method for calculating the necessary spacing between a device active region and the N-well edges in order to alleviate the N-well proximity effects.

### SUMMARY

In view of the foregoing, a semiconductor device is disclosed for alleviating well proximity effects. The semiconductor device comprises a well in a substrate, and a transistor with an active region and a gate of 0.13 um or less in gate length, wherein the gate is entirely within or extended to outside of the well, and a minimum spacing between an edge of the active region and an edge of the well is at least about 3 times the gate length.

The construction and method of operation of the invention, however, together with additional objects and advantages thereof will be best understood from the following description of specific embodiments when read in connection with the accompanying drawings.

### BRIEF DESCRIPTION OF THE DRAWINGS

The drawings accompanying and forming part of this specification are included to depict certain aspects of the invention. A clearer conception of the invention, and of the components and operation of systems provided with the invention, will become more readily apparent by referring to the exemplary, and therefore non-limiting, embodiments illustrated in the drawings, wherein like reference numbers (if they occur in more than one view) designate the same elements. The invention may be better understood by reference to one or more of these drawings in combination with the description presented herein. It should be noted that the features illustrated in the drawings are not necessarily drawn to scale.

FIG. 1 illustrates a cross-sectional diagram of an N-well implant being scattered by fixed ions inside a photoresist.

FIG. 2 is a layout diagram showing a transistor drawn inside an odd shaped N-well.

FIG. 3A shows an implant ion hitting a fixed ions.

FIG. 3B shows an implant ion 360 scattering to a certain distance into a substrate after colliding with a fixed ion of a certain height in the photoresist.

FIG. 4 is another cross-sectional view of an N-well implant ion being scattered by a fixed ion in the photoresist.

FIG. 5A and 5B are layout diagrams showing transistors drawn both inside and outside of a rectangular Nwell, respectively.

FIG. 6 is a layout diagram showing four identical transistors optimally arranged inside a rectangular well to alleviate the well proximity effect.

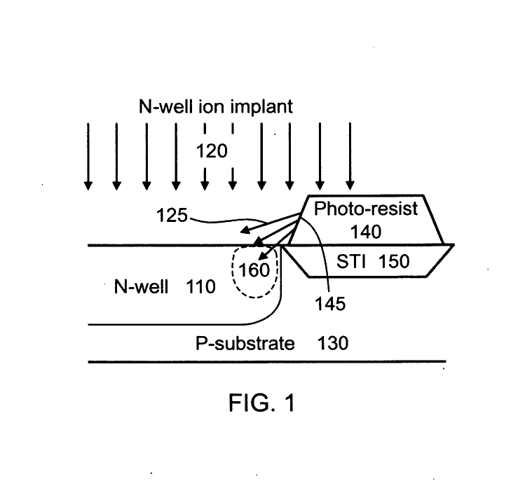

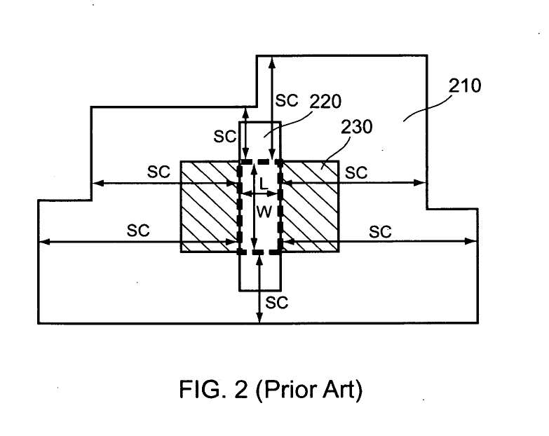

### DESCRIPTION

The invention and the various features and advantageous details thereof are explained more fully with reference to the non-limiting embodiments that are illustrated in the accompanying drawings and detailed in the following description. Descriptions of well known components and processing techniques are omitted so as not to unnecessarily obscure the invention in detail. It should be understood, however, that the detailed description and the specific examples, while indicating preferred embodiments of the invention, are given by way of illustration only and not by way of limitation. Various substitutions, modifications, additions and/or rearrangements within the spirit and/or scope of the underlying inventive concept will become apparent to those skilled in the art from this detailed description.

As aforementioned that the well proximity effects exist in more advanced, such as 0.13 um, processes. This invention provides a simple method to analyze the well proximity effects based on a trajectory of each implant particle.

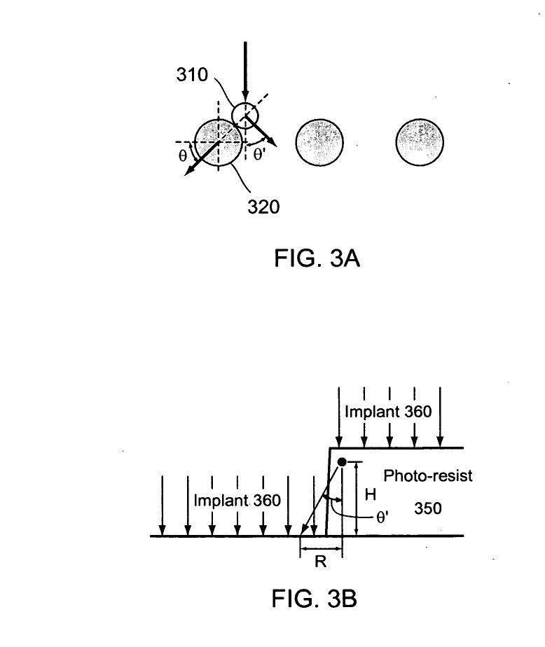

FIG. 3A shows an implant ion 310 hitting a fixed ion 320. The implant ion 310 and the fixed ions 320 have their own effective cross sections marked as circles. When the implant ion 310 collides with the fixed ion 320, the implant ion 310 scatters with anθ′ angle with respect to the incoming direction, while the fixed ion 320 moves on with a θ angle to the horizontal direction. This collision can be modeled by quasi-classic particles interacting with each other according to conservation of momentum and energy as follows:

$$\begin{matrix}ℏ {k}_{F} cos ( θ ) = ℏ {k}^{′} sin ( θ ) & Eq . 1 \\ ℏ {k}_{F} sin ( θ ) + ℏ {k}^{′} cos ( {θ}^{′} ) = ℏ k & Eq . 2 \\ \frac{{ℏ}^{2} {k}_{F}^{2}}{2 M} + \frac{{ℏ}^{2} {{k}^{′}}^{2}}{2 m} = \frac{{ℏ}^{2} {k}^{2}}{2 m} & Eq . 3\end{matrix}$$

Where, k_{F}, k′ and k are wave number of fixed, scattered and incoming ions, respectively; M and m are the masses of fixed and incoming ions; and h is Plack constant over 2π. Eqs. 1 and 2 indicate the conservation of momentum and Eq. 3 indicates the conservation of energy.

The scattered angle θ′ can be readily obtained by solving Eqs. 1, 2 and 3 as:

(m/M) sin²(θ′)+cos²(θ)=cos²(θ′−θ) Eq. 4

In general, Eq. 4 cannot be solved analytically. However, the physical meaning can be readily extracted in some particular cases:

(1) m=M. In this case, θ′=θ.

(2)m <<M. The first term on the left hand side of Eq. 4 is zero, such that θ′=θ or 180°. When the implant ion 210 is very light comparing with the fixed ion 220, it will be bounced back when encounter the fixed ion 220. In this case θ′=180 is a correct solution.

(3) m>>M. The ratio m/M becomes very large such that sin(θ′)≈0 to make both sides between 0 and 1. Therefore, θ′=0. When the implant ion 210 is very heavy, it just travels through the photoresist.

FIG. 3B shows an implant ion 360 scattering to a certain distance into a substrate after colliding with a fixed ion of a certain height in photoresist 350. The well proximity effect depends on the height (H) and scattered angle (θ′) to reach a certain distance (R), and a final energy of the scattered ions to penetrate the photoresist after scattering. The effective scattered range (R) is based on the products of the scattered angle (θ′), energy loss (E′/E), and height (H) of the photo-resist 250, such that:

$$R = H \cdot tan ( {θ}^{′} ) \cdot ( {E}^{′} / E ) = H \cdot tan ( {θ}^{′} ) \cdot \frac{{cos}^{2} ( θ )}{{cos}^{2} ( {θ}^{′} - θ )} \qquad Eq . 5$$

For m<M, the implant ions may be recoiled such that negative scattered ranges are possible. But negative scattered ranges cause no harm because the ions will not reach the substrate surface. If the scattered angle is close to 90 degrees, the scattered range may be very wide. Otherwise, the scattered ranges are usually smaller than H.

For ion implantation in integrated circuit technologies, the incoming ions are usually Boron (B, atomic weight=13), Arsenic (As, atomic weight=33), or Phosphorous (P, atomic weight=15), while the photo-resist material is usually composed of Carbon (C, atomic weight=12), Oxygen (O, atomic weight=16), or Hydrogen (H, atomic weight=1). Except Boron ions are very close to Carbon or Oxygen ions in atomic weight, either Arsenic or Phosphorous ions are much heavier than the fixed ions in the photo-resist 250. For a worst case scenario, assume that m=M, which causes θ′=0 according to Eq. 4, then Eq. 5 can be simplified as:

R=(H/2)·sin(2θ) Eq. 6

The maximum value of sin(2θ) is 1. Therefore, the maximum scattered range for m=M is:

R=(H/2) Eq. 7

where θ′=θ=45°.

It is understood that N-well proximity effect should be avoided. One way to avoid the well proximity effect is to build devices away from the edge area 160. On the other hand, the distance to the well edge should be kept at a minimum to minimize the layout area. Therefore, a properly defined layout design rule is essential. For a transistor with an active region and a gate of 0.13 um or less in gate length and is entirely within the well, a minimum spacing between an edge of the active region and an edge of the well is at least about 3 times the gate length. Besides, the depth of the well, either N-well or P-well should be kept at less than about 2 um.

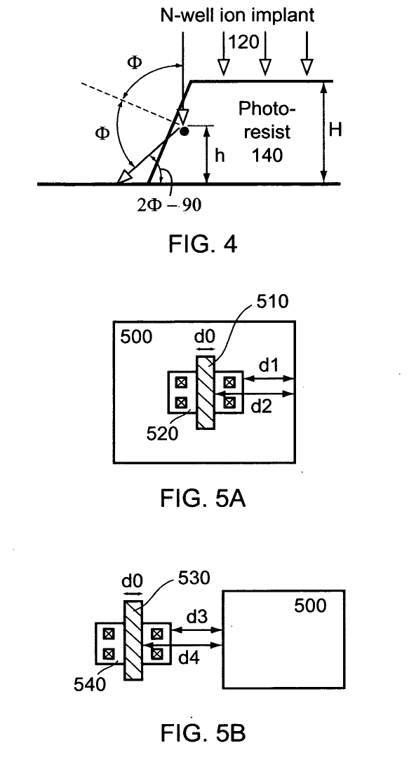

FIG. 4 shows another way of calculating the scattering range of an implant ion. Assuming that the height of the photo-resist is H and an implant ion hits a fixed ion at a height of h, then the scattering distance x of the implant ion is given by:

x=h/tan(2*Φ−90°)=−h/cot(2*Φ), (Eq. 8)

An average scatter distance x is when the ion hits the surface half way:

X=−H/(2*cot(2*Φ), (Eq. 9)

If H=1 um, Φ=60°, then x=sqrt(3)/2*H=0.86 um.

However, in practical application, IC layouts are carried out with design rules that contain numerical limits instead of equations for various dimensions. Therefore, a simpler, design rule type of well proximity effect rule is more desirable.

FIG. 5A and 5B are layout diagrams showing transistors either inside or outside a rectangular Nwell 500. FIG. 5A shows a PMOS transistor with a poly-silicon gate 510 and active region 520 drawn inside the Nwell 500. FIG. 5B shows a NMOS transistor with a poly-silicon gate 530 and an active region 540 drawn outside the Nwell 500. A minimum width of the poly-silicon gates 510 or 530 is d0. A minimum distance between an active region 520 and an edge of the Nwell 500 is d1. A minimum distance between a poly-silicon gate 510 edge over the active region 520 and an edge of the Nwell 500 is d2. Similarly, a minimum distance between an active region 540 and an edge of the Nwell 500 is d3. A minimum distance between a poly-silicon gate 530 edge over the active region 540 and an edge of the Nwell 500 is d4. When doing Nwell 500 implant, the region that contains the NMOS transistor is covered by a photoresist, wherein the Nwell proximity effect should be less severe than in the open Nwell region 500 itself. For this practical application, d1 is assumed to be equal to d3, and d2 is assumed to be equal to d4. Then Eq. 9 can be further simplified to:

d1(d3)>=3*d0 (Eq. 10)

d2(d4)>=9*d0 (Eq. 1)

When a device layout follows the design rule defined by Eq. 10 and 11, the well proximity effect can largely be ignored.

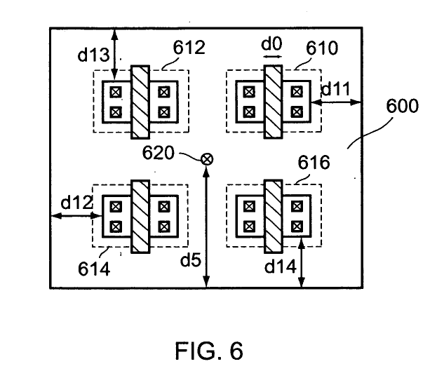

FIG. 6 is a layout diagram showing four identical transistors, 610, 612, 614 and 616, optimally arranged inside a rectangular well 600 to alleviate the well proximity effect. The transistors 610˜616 are arranged in a common centroid style for better geometric matches. Parameters d11, d12, d13 and d14 are active regions to the well edge distances, in which the Eq. 10 is still valid, i.e., the parameters are all equal to or larger than 3*d0. The parameters do not have to be the same, though they are normally set to the same number for layout simplicity.

Referring to FIG. 6, when the four transistors are placed in the common centroid style, there is a center 620 of the transistors, from where a distance to each transistor is the same. A minimum distance between the center 620 and an edge of the well 600 is d5. Then Eq. 10 can be simplified to:

d5>=18*d0 (Eq. 12)

The above illustration provides many different embodiments or embodiments for implementing different features of the invention. Specific embodiments of components and processes are described to help clarify the invention. These are, of course, merely embodiments and are not intended to limit the invention from that described in the claims.

Although the invention is illustrated and described herein as embodied in one or more specific examples, it is nevertheless not intended to be limited to the details shown, since various modifications and structural changes may be made therein without departing from the spirit of the invention and within the scope and range of equivalents of the claims. Accordingly, it is appropriate that the appended claims be construed broadly and in a manner consistent with the scope of the invention, as set forth in the following claims.

What is claimed is:

1. A semiconductor device for alleviating well proximity effects, the semiconductor device comprising:
a well in a substrate; and
a transistor with an active region and a gate of 0.13 um or less in gate length,
wherein the gate is entirely within the well, and a minimum spacing between an edge of the active region and an edge of the well is at least about 3 times the gate length.

2. The semiconductor device of claim 1, wherein the well is a N-well.

3. The semiconductor device of claim 2, wherein the depth of the N-well is less than about 2 um.

4. The semiconductor device of claim 1, wherein the well is a P-well.

5. The semiconductor device of claim 4, wherein the depth of the P-well is less than about 2 um.

6. The semiconductor device of claim 1 further comprising at least 4 transistors formed inside the N-well.

7. The semiconductor device of claim 6, wherein the transistors are symmetrically placed with a center overlaps the center of the well.

8. The semiconductor device of claim 7, wherein a distance between the center and an edge of the well is at least 18 times the gate length.

9. A semiconductor device for alleviating well proximity effects, the semiconductor device comprising:
a well in a substrate; and
a transistor with an active region and a gate of 0.13 um or less in gate length,
wherein the gate is extended to outside the well, and a minimum spacing between an edge of the active region and an edge of the well is at least 3 times the gate length.

10. The semiconductor device of claim 9, wherein the well is a N-well.

11. The semiconductor device of claim 10, wherein the depth of the N-well is less than about 2 um.

12. The semiconductor device of claim 9, wherein the well is a P-well.

13. The semiconductor device of claim 12, wherein the depth of the P-well is less than about 2 um.

14. The semiconductor device of claim 9 further comprising at least 4 transistors formed inside the N-well.

15. The semiconductor device of claim 14, wherein the transistors are symmetrically placed with a center overlaps the center of the well.

16. The semiconductor device of claim 15, wherein a distance between the center and an edge of the well is at least 18 times the gate length.

17. A semiconductor device for alleviating well proximity effects, the semiconductor device comprising:
a well in a substrate; and
a transistor with an active region and a gate of 0.13 um or less in gate length,
wherein the gate is entirely within the well, and a minimum spacing between an edge of the gate over the active region and an edge of the well is at least 9 times the gate length.

18. The semiconductor device of claim 17, wherein the well is a N-well.

19. The semiconductor device of claim 18, wherein the depth of the N-well is less than 2 um.

20. The semiconductor device of claim 17, wherein the well is a P-well.

21. The semiconductor device of claim 20, wherein the depth of the P-well is less than 2 um.

22. The semiconductor device of claim 17 further comprising at least 4 transistors formed inside the N-well.

23. The semiconductor device of claim 22, wherein the transistors are symmetrically placed with a center overlaps the center of the well.

24. The semiconductor device of claim 23, wherein a distance between the center and an edge of the well is at least 18 times the gate length.
